(19) United States
(12) Patent Application Publication
(10) Pub. No.: US 2023/0165049 A1
(43) Pub. Date: May 25, 2023

(54) METHOD OF MANUFACTURING HIGH-RESOLUTION MICRO-OLED AND DISPLAY MODULE

(71) Applicant: KUNSHAN FANTAVIEW ELECTRONIC TECHNOLOGY CO., LTD., Suzhou City, Jiangsu Province (CN)

(72) Inventors: XIAOSONG DU, Suzhou City, Jiangsu Province (CN); XIAOLONG YANG, Suzhou City, Jiangsu Province (CN); WENBIN ZHOU, Suzhou City, Jiangsu Province (CN); FENG ZHANG, Suzhou City, Jiangsu Province (CN); JIAN SUN, Suzhou City, Jiangsu Province (CN); YUDI GAO, Suzhou City, Jiangsu Province (CN)

(21) Appl. No.: 17/044,829

(22) PCT Filed: Apr. 30, 2020
(86) PCT No.: PCT/CN2020/088201

§ 371 Date: Oct. 1, 2020

(30) Foreign Application Priority Data
Nov. 13, 2019 (CN) 201911105293.9

(51) Int. Cl. H10K 59/12; H10K 59/38; H10K 59/80

(52) U.S. Cl. CPC H10K 59/1201; H10K 59/38; H10K 59/8792

(57) ABSTRACT

The present invention provides a method of manufacturing high-resolution Micro-OLED, including following steps: S1: providing a base substrate and preparing a light-emitting pixel layer on the base substrate; S2: preparing a thin film packaging layer on the light-emitting pixel layer to encapsulating the light-emitting pixel layer; S3: preparing a black matrix layer and a light converting layer for converting one color into another color on the thin film packaging layer, and the light converting layer comprising color change layer; S4: encapsulating the black matrix layer and the light converting layer to obtain high-resolution Micro-OLED. Compared with the prior arts, the method of the present invention uses the localized surface plasmon resonance effect of the metal in the light conversion layer to make the intensity of the fluorescence peak the sub-pixel increases and make the blue peak disappeared, thereby effectively improving the overall color gamut.

### CROSS-REFERENCE TO RELATED INVENTIONS

This invention is an application which claims the priority of CN application Serial No. 201911105293.9, filed on Nov. 13, 2019, and titled as “method of manufacturing high-resolution Micro-OLED and display module”, the disclosures of which are hereby incorporated by reference in their entirety.

### BACKGROUND

### 1. Technical Field

The invention relates to the field of manufacturing of the OLED (Organic Light-Emitting Diode) display, in particular to a method for manufacturing a high-resolution Micro-OLED and a display module with the high-resolution Micro-OLED.

### 2. Description of Related Art

Compared with CTR (Cathode Ray Tube) displays and TFT-LCD (Thin Film Transistor-Liquid Crystal Displays), the OLED displays have lighter and thinner design, wider viewing angle, faster response speed and lower power consumption, so that OLED displays have gradually attracted people's attention as the next generation of display devices.

The display methods for realizing full-color OLED include: RGB three-color arrangement light emitting method, blue light and light conversion layer method. Blue light and light conversion layer methods are widely used because of their low cost and simple process. However, the light conversion layer in the prior arts cannot completely absorb all the blue excitation light sources, so that each red/green sub-pixel emits red/green light accompanied by a certain proportion of blue light, which is thereby reducing the color gamut.

Hence, there is a need to provide a new method of manufacturing high-resolution Micro-OLED to solve the problems.

### SUMMARY

The objective of the present invention is to provide a method for manufacturing a high-resolution Micro-OLED, which uses the localized surface plasmon resonance effect of the metal in the light conversion layer to make the intensity of the fluorescence peak the sub-pixel increases and the blue peak disappears, thereby effectively improving the overall color gamut.

In order achieve above-mentioned objectives, the present invention provides a method of manufacturing high-resolution Micro-OLED, the method comprises following steps:

S1: providing a base substrate and preparing a light-emitting pixel layer on the base substrate;

S2: preparing a thin film packaging layer on the light-emitting pixel layer to encapsulating the light-emitting pixel layer;

S3: preparing a black matrix layer and a light converting layer for converting one color into another color on the thin film packaging layer, and the light converting layer comprising color change layer;

S4: encapsulating the black matrix layer and the light converting layer to obtain high-resolution Micro-OLED.

As an improvement of the present invention, wherein the color layer comprises quantum dot layer, a nano metal layer and a barrier layer located between the quantum dot layer and the nano metal layer.

As an improvement of the present invention, wherein a method of preparing the color change layer comprises following steps:

S31: preparing the color change layer on the thin film packaging layer;

S32: pressing a transparent quartz imprint template on the thin film packaging layer by using nanoimprint technology, and applying a certain pressure;

S33: curing by using ultraviolet light;

S34: separating the quartz imprint template from the thin film packaging layer.

As an improvement of the present invention, wherein the method of preparing the color change layer also comprises a step:

S35: cleaning the quantum dot residue left on the thin film packaging layer by using plasma cleaning technology.

As an improvement of the present invention, wherein the step S4 also comprises following steps:

S41: preparing a protective layer on the black matrix layer and the light converting layer by using an atomic layer deposition technique;

S42: encapsulating the cover plate with a photosensitive adhesive on the protective layer.

As an improvement of the present invention, wherein the protective layer is aluminum oxide.

As an improvement of the present invention, wherein the step S1 comprises following steps:

S11: providing a base substrate, and preparing a plurality of regularly arranged via holes on the base substrate;

S12: evaporating an anode layer on the base substrate by using a self-aligning process, the anode layer comprising anode units corresponding to the via holes one by one;

S13: evaporating the OLED light-emitting layer on surface of the anode layer;

S14: evaporating a cathode layer on surface of the OLED light-emitting layer to form the light-emitting pixel layer.

As an improvement of the present invention, wherein the OLED light-emitting layer is a blue organic electroluminescent device.

As an improvement of the present invention, wherein the OLED light-emitting layer comprises an organic light emitting layer, a hole injection layer and a hole transport layer located between the anode layer and the organic light emitting layer, and an electron injection layer and an electron transport layer located between the cathode layer and the organic light emitting layer.

In order achieve above-mentioned objective, the present invention also provides a display module, comprising high-resolution Micro-OLED layer and thin film transistor array electrically connected to the high-resolution Micro-OLED layer, and the high-resolution Micro-OLED layer is made by method of manufacturing high-resolution Micro-OLED as described above.

The beneficial effects of the present invention are: a method for manufacturing a high-resolution Micro-OLED of the present invention uses the localized surface plasmon resonance effect of the metal in the light conversion layer to make the intensity of the fluorescence peak the sub-pixel increases and the blue peak disappears, thereby effectively improving the overall color gamut.

### BRIEF DESCRIPTION OF THE DRAWINGS

FIG. 1 is a schematic flow chart of manufacturing method of the high-resolution Micro-OLED of the present invention.

FIG. 2 is a schematic flow chart of step S1 shown in FIG. 1.

FIG. 3 is a schematic diagram of the manufacturing process of the color change layer.

FIG. 4 is a schematic diagram of the structure of the display module of the present invention.

### DETAILED DESCRIPTION OF THE ILLUSTRATED EMBODIMENT

Reference will now be made to the drawing figures to describe the embodiments of the present disclosure in detail. In the following description, the same drawing reference numerals are used for the same elements in different drawings.

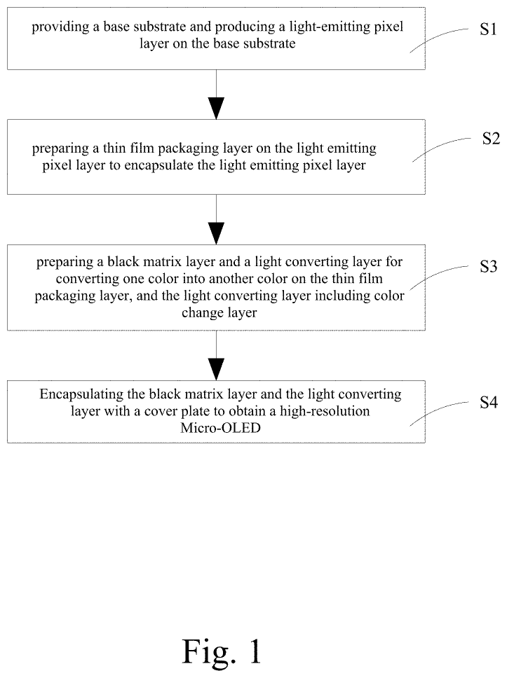

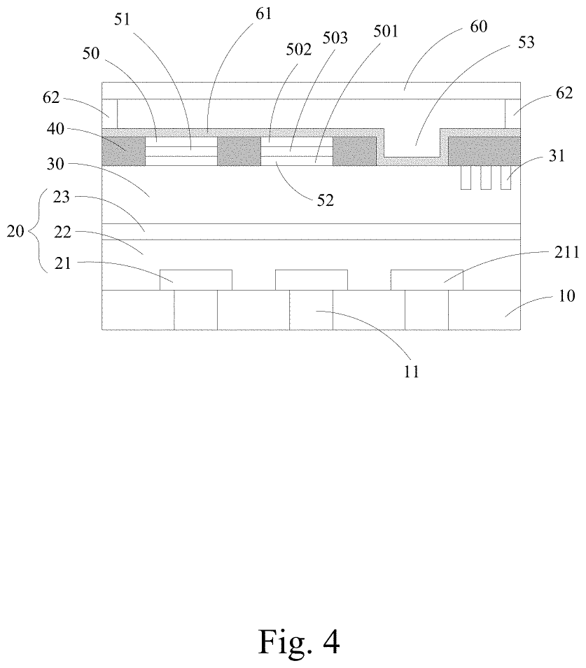

Referring to FIG. 1 and FIG. 4, a method of manufacturing a high-resolution Micro-OLED of the present invention includes the following steps:

S1: providing a base substrate 10, and producing a light-emitting pixel layer 20 on the base substrate 10.

S2: preparing a thin film packaging layer 30 on the light emitting pixel layer 20 by using thin film packaging technology, to encapsulate the light emitting pixel layer 20.

S3: preparing a black matrix layer 40 and a light converting layer 50 for converting one color into another color on the thin film packaging layer 30, and setting the black matrix layer 40 and the light converting layer 50 at intervals.

S4: Encapsulating the black matrix layer 40 and the light converting layer 50 with a cover 60 to obtain a high-resolution Micro-OLED.

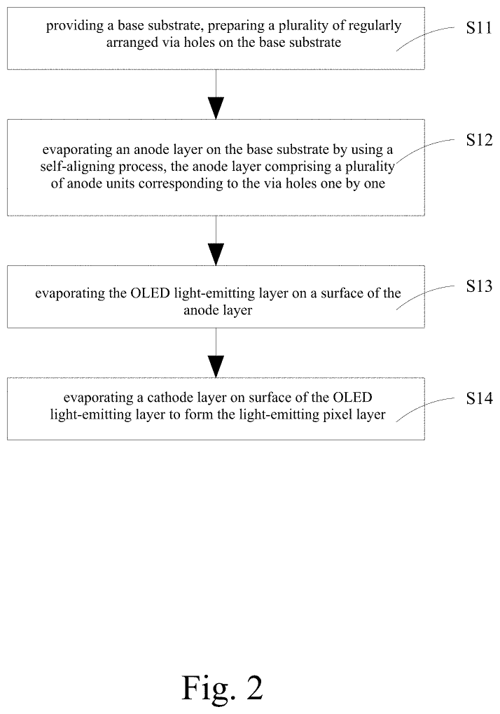

Referring to FIG. 2 and FIG. 4, the step S1 also includes the following steps:

S11: providing a base substrate 10, and preparing a plurality of regularly arranged via holes 11 on the base substrate 10.

S12: evaporating an anode layer 21 on the base substrate 10 by using a self-aligning process, the anode layer 21 comprising a plurality of anode units 211; the anode units 211 corresponding to the via holes 11 one by one.

S13: evaporating the OLED light-emitting layer 22 on a surface of the anode layer 21.

S14: evaporating a cathode layer 23 on surface of the OLED light-emitting layer 22 to form the light-emitting pixel layer 20.

The base substrate 10 is a silicon substrate. The anode layer 21 is composed of a plurality of anode units 211 arranged in a pixel pattern, and the anode units 211 are indium tin oxide film (ITO). In the present embodiment, the width of the anode unit 211 is 5 microns. The OLED light emitting layer 22 includes an organic light emitting layer, a hole injection layer and a hole transport layer located between the anode layer 21 and the organic light emitting layer, and an electron injection layer and an electron transport layer located between the cathode layer 23 and the organic light emitting layer.

Further, the hole transport layer is located between the organic light emitting layer and the hole injection layer; the electron transport layer is located between the organic light emitting layer and the electron injection layer. The cathode layer 23 is a conductive thin film layer made of metal or metal oxide material. In this embodiment, the OLED light emitting layer 22 is a blue organic electroluminescent device.

The thin film packaging layer 30 may be an organic thin film, an inorganic thin film, or an inorganic thin film stacked on an organic thin film. The film packaging layer 30 is provided with a film alignment mark 31. The film alignment mark 31 may be composed of some grid bars with a certain pitch, or may be an alignment mark composed of other forms.

Please refer to FIG. 4, the light converting layer 50 includes a first color change layer 51, a second color change layer 52, and cavities 53 arranged at intervals. The first color change layer 51 and the second color change layer 52 have the same structure, including a quantum dot layer 501, a nano metal layer 502, and a barrier layer 503 located between the quantum dot layer 501 and the nano metal layer 502. No color change layer is provided in the hole 53 so that the blue light emitted by the OLED light-emitting layer 22 can pass directly. Since the first color change layer 51 and the second color change layer 52 contain metal nanomaterials, the local surface plasmon resonance effect of the metal can be used to enhance the red and green fluorescence peaks and reduce blue light. Consequently, the color gamut is effectively improved.

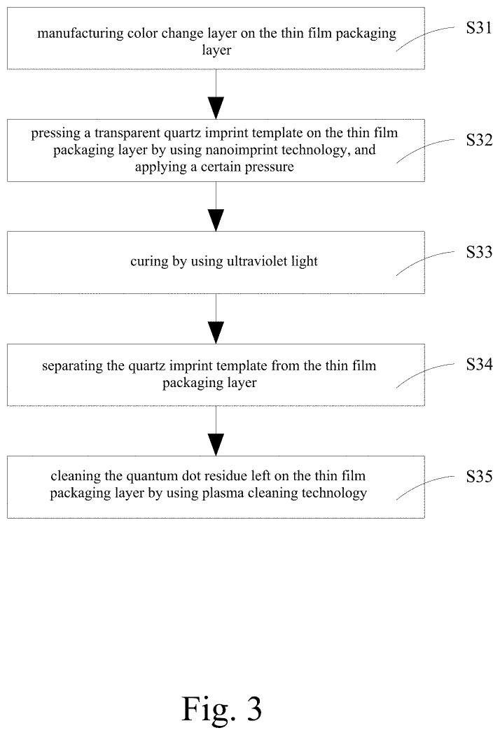

Referring to FIG. 3, a method of manufacturing the first color change layer 51 and the second color change layer 52 includes following steps:

S31: manufacturing color change layer on the thin film packaging layer 30;

S32: pressing a transparent quartz imprint template on the thin film packaging layer 30 by using nanoimprint technology, and applying a certain pressure;

S33: curing by using ultraviolet light;

S34: separating the quartz imprint template from the thin film packaging layer 30;

S35: cleaning the quantum dot residue left on the thin film packaging layer 30 by using plasma cleaning technology.

Furthermore, the step S4 also includes following steps:

S41: preparing a protective layer 61 on the black matrix layer 40 and the light conversion layer 50 by using an atomic layer deposition technique. The protective layer 61 is aluminum oxide.

S42: encapsulating the cover plate 60 with a photosensitive adhesive 62 on the protective layer 61.

The cover plate 60 can be a glass plate or a polyimide (PI) cover plate. The cover plate 60 is fixed on the protective layer 61 by photosensitive adhesive 62.

The present invention also discloses a display module, including a high-resolution Micro-OLED layer and a thin film transistor array electrically connected to the high-resolution Micro-OLED layer. The high-resolution Micro-OLED layer is made by the manufacturing method of high-resolution Micro-OLED of the present invention.

Compared with the prior art, the method of manufacturing the high-resolution Micro-OLED of the present invention utilizes the localized surface plasmon resonance effect of the metal in the light conversion layer 50 to increase the intensity of the fluorescence peak in the sub-pixel, and make the blue peak disappeared, so that the overall color gamut is effectively improved.

It is to be understood, however, that even though numerous characteristics and advantages of preferred and exemplary embodiments have been set out in the foregoing description, together with details of the structures and functions of the embodiments, the disclosure is illustrative only; and that changes may be made in detail within the principles of present disclosure to the full extent indicated by the broadest general meaning of the terms in which the appended claims are expressed.

1. A method of manufacturing high-resolution Micro-OLED, wherein the method comprises following steps:
S1: providing a base substrate and preparing a light-emitting pixel layer on the base substrate;
S2: preparing a thin film packaging layer on the light-emitting pixel layer to encapsulating the light-emitting pixel layer;
S3: preparing a black matrix layer and a light converting layer for converting one color into another color on the thin film packaging layer, and the light converting layer comprising color change layer;
S4: encapsulating the black matrix layer and the light converting layer to obtain high-resolution Micro-OLED.

2. The method of manufacturing high-resolution Micro-OLED as claimed in claim 1, wherein the color layer comprises quantum dot layer, a nano metal layer and a barrier layer located between the quantum dot layer and the nano metal layer.

3. The method of manufacturing high-resolution Micro-OLED as claimed in claim 2, wherein a method of preparing the color change layer comprises following steps:
S31: preparing the color change layer on the thin film packaging layer;
S32: pressing a transparent quartz imprint template on the thin film packaging layer by using nanoimprint technology, and applying a certain pressure;
S33: curing by using ultraviolet light;
S34: separating the quartz imprint template from the thin film packaging layer.

4. The method of manufacturing high-resolution Micro-OLED as claimed in claim 3, wherein the method of preparing the color change layer also comprises a step:
S35: cleaning the quantum dot residue left on the thin film packaging layer by using plasma cleaning technology.

5. The method of manufacturing high-resolution Micro-OLED as claimed in claim 1, wherein the step S4 also comprises following steps:
S41: preparing a protective layer on the black matrix layer and the light converting layer by using an atomic layer deposition technique;
S42: encapsulating the cover plate with a photosensitive adhesive on the protective layer.

6. The method of manufacturing high-resolution Micro-OLED as claimed in claim 5, wherein the protective layer is aluminum oxide.

7. The method of manufacturing high-resolution Micro-OLED as claimed in claim 1, wherein the step S1 comprises following steps:
S11: providing a base substrate, and preparing a plurality of regularly arranged via holes on the base substrate;
S12: evaporating an anode layer on the base substrate by using a self-aligning process, the anode layer comprising anode units corresponding to the via holes one by one;
S13: evaporating the OLED light-emitting layer on surface of the anode layer;
S14: evaporating a cathode layer on surface of the OLED light-emitting layer to form the light-emitting pixel layer.

8. The method of manufacturing high-resolution Micro-OLED as claimed in claim 7, wherein the OLED light-emitting layer is a blue organic electroluminescent device.

9. The method of manufacturing high-resolution Micro-OLED as claimed in claim 7, wherein the OLED light-emitting layer comprises an organic light emitting layer, a hole injection layer and a hole transport layer located between the anode layer and the organic light emitting layer, and an electron injection layer and an electron transport layer located between the cathode layer and the organic light emitting layer.

10. A display module, comprising high-resolution Micro-OLED layer and thin film transistor array electrically connected to the high-resolution Micro-OLED layer, and wherein the high-resolution Micro-OLED layer is made by method of manufacturing high-resolution Micro-OLED as claimed in claim 1.

11. The display module as claimed in claim 10, wherein the color layer comprises quantum dot layer, a nano metal layer and a barrier layer located between the quantum dot layer and the nano metal layer.

12. The display module as claimed in claim 11, wherein a method of preparing the color change layer comprises following steps:
S31: preparing the color change layer on the thin film packaging layer;
S32: pressing a transparent quartz imprint template on the thin film packaging layer by using nanoimprint technology, and applying a certain pressure;
S33: curing by using ultraviolet light;
S34: separating the quartz imprint template from the thin film packaging layer.

13. The display module as claimed in claim 12, wherein the method of preparing the color change layer also comprises a step:
S35: cleaning the quantum dot residue left on the thin film packaging layer by using plasma cleaning technology.

14. The display module as claimed in claim 10, wherein the step S4 also comprises following steps:
S41: preparing a protective layer on the black matrix layer and the light converting layer by using an atomic layer deposition technique;
S42: encapsulating the cover plate with a photosensitive adhesive on the protective layer.

15. The display module as claimed in claim 14, wherein the protective layer is aluminum oxide.

16. The display module as claimed in claim 10, wherein the step S1 comprises following steps:
S11: providing a base substrate, and preparing a plurality of regularly arranged via holes on the base substrate;
S12: evaporating an anode layer on the base substrate by using a self-aligning process, the anode layer comprising anode units corresponding to the via holes one by one;
S13: evaporating the OLED light-emitting layer on surface of the anode layer;
S14: evaporating a cathode layer on surface of the OLED light-emitting layer to form the light-emitting pixel layer.

17. The display module as claimed in claim 16, wherein the OLED light-emitting layer is a blue organic electroluminescent device.

18. The display module as claimed in claim 16, wherein the OLED light-emitting layer comprises an organic light emitting layer, a hole injection layer and a hole transport layer located between the anode layer and the organic light emitting layer, and an electron injection layer and an electron transport layer located between the cathode layer and the organic light emitting layer.
